(19) United States
(12) Patent Application Publication
(10) Pub. No.: US 2025/0311487 A1
(43) Pub. Date: Oct. 2, 2025

(54) LIGHT-EMITTING DIODE AND LIGHT-EMITTING DEVICE

(71) Applicant: Xiamen San'an Optoelectronics Co., Ltd., Fujian (CN)

(72) Inventors: Yunan WANG, Fujian (CN); Jingfeng HUANG, Fujian (CN); Chaohsu LAI, Fujian (CN); Hsin-yu LIU, Fujian (CN); Chung-ying CHANG, Fujian (CN)

(73) Assignee: Xiamen San'an Optoelectronics Co., Ltd., Fujian (CN)

(21) Appl. No.: 19/238,534

(22) Filed: Jun. 16, 2025

Related U.S. Application Data
(63) Continuation of application No. PCT/CN2023/136089, filed on Dec. 4, 2023.

(30) Foreign Application Priority Data
Dec. 16, 2022 (CN) 202211621641.X

(51) Int. Cl. H10H 20/816; H10H 20/81; H10H 20/812; H10H 20/825; H10H 20/83; H10H 20/84

(52) U.S. Cl. CPC H10H 20/8162; H10H 20/812; H10H 20/8215; H10H 20/825; H10H 20/83; H10H 20/84

(57) ABSTRACT

The present disclosure relates to semiconductor manufacturing technology, particularly relates to a light-emitting diode, which includes a light-emitting layer, an N-type semiconductor layer, a P-type semiconductor layer, an electron blocking layer and a connecting layer. The light- emitting layer has a first side and a second side opposite to each other. The N-type semiconductor layer is disposed on the first side of the light-emitting layer. The P-type semiconductor layer is disposed on the second side of the light-emitting layer. The electron blocking layer is disposed between the light-emitting layer and the P-type semiconductor layer. The connecting layer is disposed between the light-emitting layer and the electron blocking layer, wherein, the connecting layer is doped with indium.

### CROSS-REFERENCE TO RELATED APPLICATION

This application is a continuation of international application of PCT application serial no. PCT/CN2023/136089, filed on Dec. 4, 2023, which claims the priority benefit of China application serial no. 202211621641.X, filed on Dec. 16, 2022. The entirety of each of the above-mentioned patent applications is hereby incorporated by reference herein and made a part of this specification.

### BACKGROUND

### Technical Field

The present disclosure relates to semiconductor manufacturing technology, and particularly relates to a light-emitting diode and a light-emitting device.

### Description of Related Art

A light-emitting diode (LED) constitutes a semiconductor light-emitting element, typically manufactured from semiconductors such as GaN, GaAs, GaP, GaAsP, and other similar materials, wherein the core element thereof includes a PN junction possessing luminescent property. LEDs exhibit advantages including high luminous intensity, superior efficiency, compact dimensions, and extended operational lifespan, thereby being recognized as one of the most promising light sources currently available. LEDs have been extensively implemented across various applications including illumination, surveillance and command systems, high- definition broadcasting, premium cinema installations, office display systems, conference interactive technologies, and virtual reality platforms.

In the course of implementing the present disclosure, the inventors found that the related art has at least the following problems: current gallium nitride LEDs suffer from low hole injection efficiency and poor radiative recombination efficiency. Particularly in gallium nitride Micro LEDs, the problem of low radiative recombination efficiency is worse due to the small chip size. It should be noted that the information disclosed in this background technology section

is merely intended to enhance understanding of the general background of the present disclosure, and should not be regarded as an acknowledgment or any form of suggestion that this information constitutes related art already known to those of ordinary skill in the art.

### SUMMARY

The present disclosure provides a light-emitting diode, including a light-emitting layer, an N-type semiconductor layer, a P-type semiconductor layer, an electron blocking layer and a connecting layer.

The light-emitting layer has a first side and a second side. The N-type semiconductor layer is disposed on the first side of the light-emitting layer. The P-type semiconductor layer is disposed on the second side of the light-emitting layer. The electron blocking layer is disposed between the light-emitting layer and the P-type semiconductor layer. The connecting layer is disposed between the light-emitting layer and the electron blocking layer, and the connecting layer is doped with indium. The connecting layer is doped with indium, such that an energy barrier between the electron blocking layer and the connecting layer may be effectively reduced, which facilitates hole injection. Moreover, due to the reduction in energy barrier, hole injection in the light-emitting layer will increase and radiative recombination may also be enhanced, thereby improving the optoelectronic quality of the light-emitting diode.

In some embodiments, a material of the connecting layer includes AlGaN or GaN, and a material of the electron blocking layer includes AlGaN or AlGaInN. With the combination of the above materials, the connecting layer doped with indium has improved energy barrier reduction effect, further enhancing the radiative recombination efficiency in the light-emitting layer and enhancing the optoelectronic quality of the light-emitting diode.

In some embodiments, considering that indium is not necessarily better in greater quantities, as excessive indium may adversely affect the optoelectronic property of the light-emitting diode, a proportion of indium doped in the connecting layer ranges from 0.1% to 30%.

In some embodiments, a concentration of indium doped in the connecting layer ranges from 1E16 cm⁻³ to 1E21 cm⁻³. The concentration range enhances the energy barrier reduction effect of the connecting layer, further enhancing the radiative recombination efficiency in the light-emitting layer.

In some embodiments, a thickness of the connecting layer is 1% to 900% of a thickness of the light-emitting layer, and the thickness of the connecting layer ranges from 1 angstrom to 500 angstroms.

In some embodiments, a thickness of the electron blocking layer is 1% to 3000% of the thickness of the light-emitting layer.

In some embodiments, a content of aluminum in the electron blocking layer ranges from 15% to 20%.

In some embodiments, the thickness of the connecting layer is less than the thickness of the electron blocking layer.

In some embodiments, a concentration of indium doped in the connecting layer is uniformly distributed.

In some embodiments, the concentration of indium doped in the connecting layer gradually decreases in a direction from the P-type semiconductor layer toward the N-type semiconductor layer, and the thickness of the connecting layer ranges from 500 angstroms to 900 angstroms.

In some embodiments, the concentration of indium doped in the connecting layer on one side close to the P-type semiconductor layer is at least 1.5 times the concentration of indium doped in the connecting layer on one side close to the N-type semiconductor layer.

In some embodiments, the light-emitting diode further includes an N-type electrode, a P-type electrode and an insulation layer. The insulation layer covers the P-type semiconductor layer, the light-emitting layer and the N-type semiconductor layer. The insulation layer has a first opening and a second opening. The N-type electrode is connected to the N-type semiconductor layer through the first opening. The P-type electrode is connected to the P-type semiconductor layer through the second opening.

In some embodiments, the proportion of indium doped in the connecting layer ranges from 0.1% to 5%.

In some embodiments, the light-emitting diode is a gallium nitride light-emitting diode.

The present disclosure further provides a light-emitting device. The light-emitting device includes a circuit board and a light-emitting diode. The light-emitting diode is disposed on the circuit board. The light-emitting diode may adopt the light-emitting diode provided in any of the above embodiments.

In a light-emitting diode and a light-emitting device provided by an embodiment of the present disclosure, by incorporating indium in the connecting layer, it is possible to effectively reduce the energy barrier between the electron blocking layer and the connecting layer, which facilitates hole injection. Moreover, since the energy barrier is reduced, the hole injection in the light-emitting layer will increase and radiative recombination may also be enhanced, ultimately enhancing the optoelectronic quality of the light-emitting diode. The principle mainly lies in that: along a direction from the electron blocking layer to the light-emitting layer, since the energy gap changes from large to small, the energy band transition is relatively drastic within this range. In order to enhance the hole injection efficiency, by incorporating indium (a material with narrower bandgap) into the connecting layer to reduce the energy barrier between the electron blocking layer and the connecting layer, this reduction of energy gap helps to increase hole injection, thereby further enhancing the radiative recombination efficiency in the light-emitting layer, and improving the optoelectronic quality of the light-emitting diode.

Other characteristics and advantageous effects of the present disclosure will be set forth in the following specification, and some of the technical characteristics and advantageous effects may be obviously derived from the specification, or understood through implementation of the present disclosure.

### BRIEF DESCRIPTION OF THE DRAWINGS

In order to more clearly describe the technical solutions in the embodiments of the present disclosure or the related art, the following will briefly introduce the drawings required for use in the description of the embodiments or the related art. Clearly, some of the drawings in the following description are some embodiments of the present disclosure. For those of ordinary skill in the art, other drawings may also be obtained according to these drawings without creative effort.

FIG. 1 is a structural schematic diagram of a light-emitting diode provided by an embodiment of the present disclosure.

FIG. 2 is a structural diagram of a top view of a light-emitting diode provided by an embodiment of the present disclosure.

FIG. 3 is a schematic diagram of the content of each element in the electron blocking layer, the connecting layer and the light-emitting layer of FIG. 1.

### DESCRIPTION OF THE EMBODIMENTS

To make the objectives, technical solutions and advantages of the embodiments of the present disclosure clearer, the technical solutions in the embodiments of the present disclosure will be described clearly and thoroughly in conjunction with the drawings in the embodiments of the present disclosure. Clearly, the described embodiments are part of the embodiments of the present disclosure, rather than all of the embodiments. The technical characteristics designed in different embodiments of the present disclosure described below may be combined with each other as long as they do not conflict with each other. Based on the embodiments in the present disclosure, all other embodiments obtained by those of ordinary skill in the art without creative effort fall within the scope to be protected by the present disclosure.

In the description of the present disclosure, it should be understood that the orientations or positional relationships indicated by the terms “center”, “lateral”, “upper”, “lower”, “left”, “right”, “vertical”, “horizontal”, “top”, “bottom”, “inner”, “outer”, and the like are based on the orientations or positional relationships shown in the drawings, and are only for the convenience of describing the present disclosure and simplifying the description, rather than indicating or implying that the referred device or component must have a specific orientation, or be constructed and operated in a specific orientation, and therefore should not be understood as limitations on the present disclosure. In addition, the terms “first” and “second” are only used for descriptive purposes, and should not be understood as indicating or implying relative importance or implicitly indicating the number of the indicated technical characteristics. Thus, characteristics defined with “first” and “second” may explicitly or implicitly include one or more of such characteristics. In the description of the present disclosure, unless otherwise specified, “multiple” means two or more. In addition, the term “include” and any variations thereof all mean “at least include”.

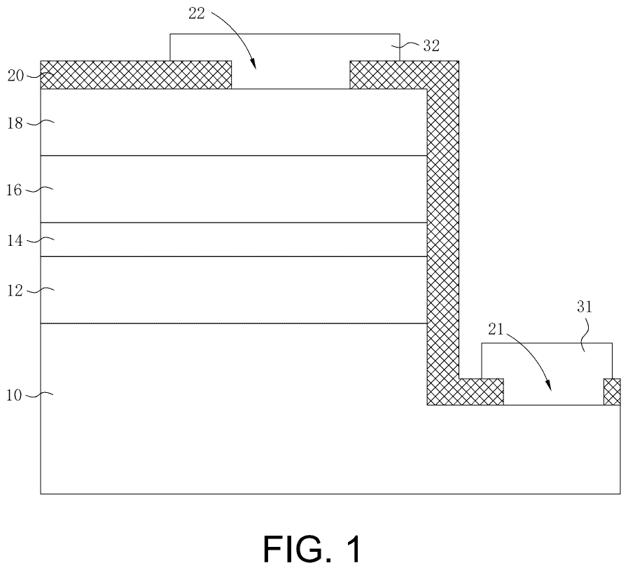

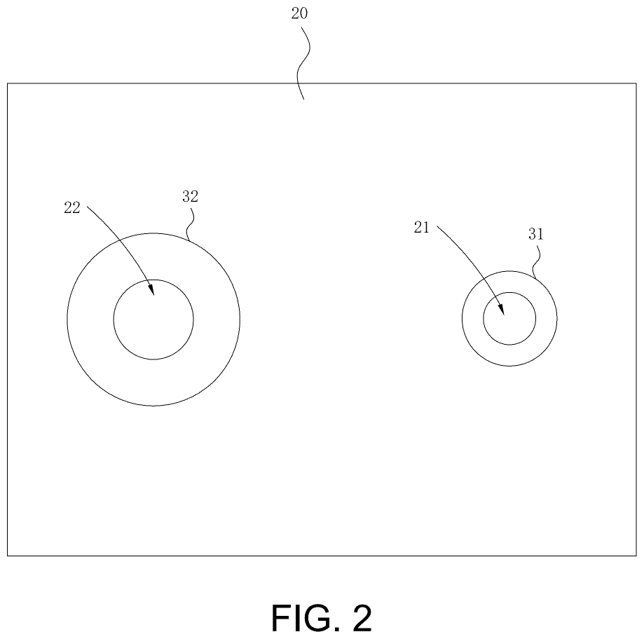

Please refer to FIG. 1 and FIG. 2. FIG. 1 is a structural schematic diagram of a light-emitting diode provided by an embodiment of the present disclosure. FIG. 2 is a structural diagram of a top view of a light-emitting diode provided by an embodiment of the present disclosure. To achieve at least one of the aforementioned advantages or other advantages, an embodiment of the present disclosure provides a light-emitting diode. As shown in the figures, the light-emitting diode may include a light-emitting layer 12, an N-type semiconductor layer 10, a P-type semiconductor layer 18, an electron blocking layer 16 and a connecting layer 14.

The light-emitting layer 12 has a first and a second side opposite to each other. In the present embodiment, the first side and the second side of the light-emitting layer 12 are a lower side and an upper side respectively. The light-emitting layer 12 may be a quantum well (abbreviated as QW) structure. In some embodiments, the light-emitting layer 12 may also be a multiple quantum well (abbreviated as MQW) structure, wherein the multiple quantum well structure includes multiple quantum well layers and multiple quantum barrier layers alternately arranged in a repetitive manner, for example, the multiple quantum well structure may be a multiple quantum well structure of GaN/AlGaN, InAlGaN/InAlGaN or InGaN/AlGaN. In addition, the composition and thickness of well layers in the light-emitting layer 12 determine a wavelength of a generated light. A light-emitting efficiency of the light-emitting layer 12 may be improved by changing a depth of quantum wells, the number of layers, thickness and/or other characteristics of paired quantum wells and quantum barriers in the light-emitting layer 12.

The N-type semiconductor layer 10 is disposed on the first side of the light-emitting layer 12, and may provide electrons to the light-emitting layer 12 under an action of a power source. In some embodiments, the N-type semiconductor layer 10 includes an N-type doped nitride layer. The N-type doped nitride layer may include N-type impurities of one or more Group IV elements. The N-type impurities may include one of Si, Ge, Sn or combinations thereof. In some embodiments, a buffer layer may also be disposed between the N-type semiconductor layer 10 and a substrate to reduce a lattice mismatch between the substrate and the N-type semiconductor layer 10. The buffer layer may include an unintentionally doped GaN (abbreviated as: u-GaN) layer.

The P-type semiconductor layer 18 is disposed on the second side of the light-emitting layer 12, and may provide holes to the light-emitting layer 12 under the action of the power source. The P-type semiconductor layer 18 includes a P-type doped nitride layer. The P-type doped nitride layer may include one or more P-type impurities. The P-type impurities may include one of Mg, Zn, Be or combinations thereof. The P-type semiconductor layer 18 may be a single-layer structure or a multi-layer structure having different compositions.

The electron blocking layer 16 is disposed between the light-emitting layer 12 and the P-type semiconductor layer 18, and mainly serves a function of blocking electrons. By disposing the electron blocking layer 16 between the light-emitting layer 12 and the P-type semiconductor layer 18, a conduction band barrier height is made greater than a conduction band height of the quantum wells and the quantum barriers of the light-emitting layer 12, thereby enabling electrons to enter the P-type semiconductor layer 18 only with higher thermal kinetic energy, so that electrons may be effectively confined within the light-emitting layer 12.

The connecting layer 14 is disposed between the light-emitting layer 12 and the electron blocking layer 16, and serves to connect the upper structural layer and lower structural layer. Considering that a material of the connecting layer grown in current blue-green gallium nitride LEDs typically adopts AlGaN or GaN, as a connecting layer between the light-emitting layer and the electron blocking (EBL) layer, which mainly serves a connecting function, a material of the electron blocking layer normally adopts AlGaN or AlGalInN. In the process of implementing the present disclosure, the inventors found that the related art at least has the following problems: in current gallium nitride LEDs, although the connecting layer formed of AlGaN or GaN material to connect with the electron blocking layer may serve a connecting function, a contact interface between the connecting layer and the electron blocking layer is not easy for hole injection, which may reduce LED quality.

The present disclosure may effectively reduce the energy barrier between the electron blocking layer 16 and the connecting layer 14 by doping indium in the connecting layer 14, which facilitates hole injection. Moreover, since the energy barrier is reduced, hole injection within the light-emitting layer 12 may increase and radiative recombination may also be enhanced, ultimately enhancing the optoelectronic quality of the light-emitting diode. The principle mainly lies in that: along a direction from the electron blocking layer 16 to the light-emitting layer 12, since the energy gap changes from large to small, the energy band transition is relatively drastic within this range. In order to enhance the hole injection efficiency, by incorporating indium (a material with narrower bandgap) in the connecting layer 14 to reduce the energy barrier between the electron blocking layer 16 and the connecting layer 14, this reduction of energy gap helps to increase hole injection, thereby further enhancing the radiative recombination efficiency in the light-emitting layer 12, and improving the optoelectronic quality of the light-emitting diode. Under applications of different current densities, the light-emitting diode with this structure may enhance overall luminance by 1% to 15%.

Regarding doping indium in the connecting layer 14, a vapor phase epitaxy method may be adopted. During the process of preparing the connecting layer 14 on the light-emitting layer 12 by vapor phase epitaxy, by introducing indium gas, the connecting layer 14 doped with indium may be obtained.

In some embodiments, the material of the connecting layer 14 includes AlGaN or GaN,

and the material of the electron blocking layer 16 includes AlGaN or AlGaInN. Through the combination of the above materials, the connecting layer 14 doped with indium has an improved energy barrier reduction effect, thus further enhancing radiative recombination efficiency within the light-emitting layer 12 and enhancing the optoelectronic quality of the light-emitting diode. In some embodiments, considering that indium is doped in the connecting layer 14, the content of aluminum in the electron blocking layer 16 may be appropriately enhanced, for example, the content of aluminum in the electron blocking layer 16 ranges from 15% to 20%, which may further reduce the energy barrier between the electron blocking layer 16 and the connecting layer 14 to facilitate hole injection.

In some embodiments, considering that indium is not necessarily better in greater

quantities, as excessive indium may adversely affect the optoelectronic property of the light-emitting diode, a proportion of indium doped in the connecting layer 14 ranges from 0.1% to 30%. Preferably, the proportion of indium doped in the connecting layer 14 preferably ranges from 0.1% to 5%. If the doped indium is too little, it may be difficult to achieve the effect of reducing the energy barrier between the electron blocking layer 16 and the connecting layer 14. If the doped indium is greater than 5%, the crystal quality of the connecting layer 14 might be affected, thereby causing poor optoelectronic property of the light-emitting diode.

In some embodiments, for enhancing reduction of the energy barrier of the connecting layer 14 and avoiding degradation of the crystal quality to further improve radiative recombination efficiency within the light-emitting layer 12, the concentration of indium doped in the connecting layer 14 preferably ranges from 1E16 cm⁻³ to 1E21 cm⁻³.

In some embodiments, for enhancing reduction of the energy barrier of the connecting layer 14 and enhancing radiative recombination efficiency within the light-emitting layer 12, a thickness of the connecting layer 14 is 1% to 900% of a thickness of the light-emitting layer 12, and the thickness of the connecting layer 14 ranges from 1 angstrom to 500 angstroms. Preferably, the thickness of the connecting layer 14 is 1% to 5% of the thickness of the light-emitting layer 12 to enhance the radiative recombination efficiency. A thickness of the electron blocking layer 16 is 1% to 3000% of the thickness of the light-emitting layer 12. The thickness of the connecting layer 14 is less than the thickness of the electron blocking layer 16.

In some embodiments, the concentration of indium doped in the connecting layer 14 is uniformly distributed, that is to say, the indium doped in the connecting layer 14 has substantially the same concentration along a top-to-bottom direction, which makes it possible to enhance the energy barrier reduction effect of the connecting layer 14 and further improve radiative recombination efficiency within the light-emitting layer 12.

For example, the connecting layer 14 is divided along the top-to-bottom direction into a first region, a second region, a third region, and a fourth region, with each region accounting for 25% of the thickness of the connecting layer 14. An average concentration of indium doped in the first region approximates an average concentration of indium doped in the second region, the average concentration of indium doped in the second region approximates that in the third region, and the average concentration of indium doped in the third region approximates that in the fourth region. An approximate value may refer to a value that differs by less than 5%.

However, the present disclosure is not limited thereto. In some embodiments, the thickness of the connecting layer 14 ranges from 500 angstroms to 900 angstroms. When the thickness of the connecting layer 14 is relatively large, the concentration of indium doped in the connecting layer 14 may also be gradually reduced in a direction from the P-type semiconductor layer 18 toward the N-type semiconductor layer 10, that is to say, the indium doped in the connecting layer 14 has a concentration that is gradually reduced along the top-to-bottom direction. In this way, it may also be possible to enhance the energy barrier reduction effect of the connecting layer 14 and further improve the radiative recombination efficiency within the light-emitting layer 12. Preferably, the concentration of indium doped in the connecting layer 14 on one side close to the P-type semiconductor layer 18 is at least 1.5 times the concentration of indium doped in the connecting layer 14 on one side close to the N-type semiconductor layer 10, which further facilitates the energy barrier reduction effect of the connecting layer 14.

For example, the connecting layer 14 is divided into the first region, the second region, the third region, and the fourth region along the top-to-bottom direction, with each region accounting for 25% of the thickness of the connecting layer 14. The concentration of indium doped in the first region is higher than the concentration of indium doped in the second region, the concentration of indium doped in the second region is higher than that in the third region, and the concentration of indium doped in the third region is higher than that in the fourth region. The concentration in each of the above regions is an average concentration. Through the design where the concentration of indium doped in the connecting layer 14 gradually reduces from top to bottom, it is possible to enhance the energy barrier reduction effect of the connecting layer 14 and further improve the radiative recombination efficiency within the light-emitting layer 12.

In some embodiments, as shown in FIG. 1, the light-emitting diode may further include an N-type electrode 31, a P-type electrode 32, and an insulation layer 20. The insulation layer 20 covers the P-type semiconductor layer 18, the light-emitting layer 12, and the N-type semiconductor layer 10. The insulation layer 20 has a first opening 21 and a second opening 22, where the first opening 21 exposes the N-type electrode 31 and the second opening 22 exposes the P-type electrode 32. A material of the insulation layer 20 includes a non-conductive material. The non-conductive material is preferably an inorganic material or a dielectric material. The inorganic material may include silicone. The dielectric material includes electrically insulating materials such as aluminum oxide, silicon nitride, silicon oxide, titanium oxide, or magnesium fluoride. For example, the insulation layer 20 may be silicon dioxide, silicon nitride, titanium oxide, tantalum oxide, niobium oxide, barium titanate, or combinations thereof, where the combination may be, for example, a Bragg reflector (DBR) formed by repeatedly stacking two materials with different refractive indices.

The N-type electrode 31 is disposed on the insulation layer 20 and connected to the N-type semiconductor layer 10 through the first opening 21. The N-type electrode 31 may be a single-layer, a double-layer, or a multi-layer structure, for example: Ti/Al, Ti/Al/Ti/Au, Ti/Al/Ni/Au, V/Al/Pt/Au, and other stacked metal structures.

The P-type electrode 32 is disposed on the insulation layer 20 and connected to the P-type semiconductor layer 18 through the second opening 22. The P-type electrode 32 may be fabricated from a transparent conductive material or may be fabricated from a metal material, which may be adaptively selected according to the doping condition of a surface layer (such as p-type GaN surface layer) of the P-type semiconductor layer 18. In some embodiments, the P-type electrode 32 is fabricated from the transparent conductive material, and the material may include indium tin oxide (ITO), indium zinc oxide (IZO), indium oxide (InO), tin oxide (SnO), cadmium tin oxide (CTO), antimony tin oxide (ATO), aluminum zinc oxide (AZO), zinc tin oxide (ZTO), gallium doped zinc oxide (GZO), tungsten doped indium oxide (IWO), or zinc oxide (ZnO), but embodiments of the present disclosure are not limited thereto.

In some embodiments, the light-emitting diode may be a gallium nitride light-emitting diode, and the connecting layer 14 doped with indium has an improved effect to reduce energy barrier in the gallium nitride light-emitting diode, which may further enhance the radiative recombination efficiency in the light-emitting layer 12.

By using the light-emitting diode provided by the present disclosure, the overall luminance of the light-emitting diode of the present disclosure may be enhanced by approximately 0.5% to 1.4% compared with conventional LEDs, and an operating voltage may be slightly reduced by approximately 0.006V, thereby obtaining a light-emitting diode with higher optoelectronic quality.

The present disclosure further provides a light-emitting device, the light-emitting device includes a circuit board and a light-emitting diode. The light-emitting diode is disposed on the circuit board, and the light-emitting diode may adopt the light-emitting diode provided by any of the above embodiments. The light-emitting diode may be a micro LED, which is mainly applied in lasers, and a side length dimension of the micro LED is less than 100 μm.

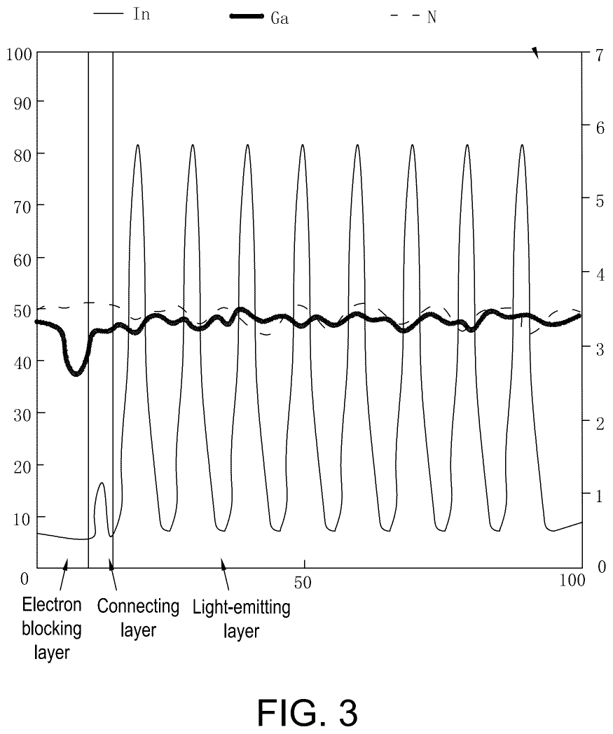

As a supplementary explanation, EDX (Energy Dispersive X-Ray Spectroscopy, which determines the contained elements and content of the elements according to different x-ray wavelengths corresponding to the elements) may be used to detect whether the connecting layer 14 is doped with indium. FIG. 3 is a schematic diagram of the content of each element in the electron blocking layer, the connecting layer and the light-emitting layer of FIG. 1. As shown in FIG. 3, FIG. 3 is a schematic diagram of the content of each element in the electron blocking layer 16, the connecting layer 14, and the light-emitting layer 12, where the horizontal axis in the figure represents the relative positional relationship of each structural layer with a unit of nm, the left vertical axis in the figure represents the content percentage of Ga element and N element, and the right vertical axis in the figure represents the content percentage of In element. It may be seen that the content of indium in the connecting layer 14 is approximately 1.2%, which may effectively reduce the energy barrier between the electron blocking layer 16 and the connecting layer 14, thus facilitating hole injection.

In summary, by doping indium in the connecting layer 14, a light-emitting diode and a light-emitting device provided by an embodiment of the present disclosure may effectively reduce the energy barrier between the electron blocking layer 16 and the connecting layer 14, thus facilitating hole injection. Moreover, since the energy barrier is reduced, the hole injection in the light-emitting layer 12 may be increased and radiative recombination may also be enhanced, ultimately enhancing the optoelectronic quality of the light-emitting diode.

In addition, those skilled in the art should understand that although there are many problems in the related art, each embodiment or technical solution of the present disclosure may make improvement in only one or several aspects, and does not have to simultaneously solve all the technical problems listed in the related art or background technology. Those skilled in the art should understand that content not mentioned in a claim should not be regarded as a limitation to that claim.

Finally, it should be noted that: the above embodiments are only used to illustrate the technical solutions of the present disclosure, rather than to limit them; although the present disclosure has been described in detail with reference to the aforementioned embodiments, those of ordinary skill in the art should understand that: they may still modify the technical solutions described in the aforementioned embodiments, or make equivalent substitutions for some or all of the technical characteristics thereof; and these modifications or substitutions do not cause the essence of the corresponding technical solutions to depart from the scope of the technical solutions of the embodiments of the present disclosure.

What is claimed is:

1. A light-emitting diode, characterized in that the light-emitting diode comprises:
a light-emitting layer, having a first side and a second side opposite to each other;
an N-type semiconductor layer, disposed on the first side of the light-emitting layer;
a P-type semiconductor layer, disposed on the second side of the light-emitting layer;
an electron blocking layer, disposed between the light-emitting layer and the P-type semiconductor layer;
a connecting layer, disposed between the light-emitting layer and the electron blocking layer;
wherein the connecting layer is doped with indium.

2. The light-emitting diode according to claim 1, characterized in that a material of the connecting layer comprises AlGaN or GaN, and a material of the electron blocking layer comprises AlGaN or AlGaInN.

3. The light-emitting diode according to claim 1, characterized in that a proportion of the indium doped in the connecting layer ranges from 0.1% to 30%.

4. The light-emitting diode according to claim 1, characterized in that a concentration of the indium doped in the connecting layer ranges from 1E16 cm⁻³ to 1E21 cm⁻³.

5. The light-emitting diode according to claim 1, characterized in that a thickness of the connecting layer is 1% to 900% of a thickness of the light-emitting layer, and the thickness of the connecting layer ranges from 1 angstrom to 500 angstroms.

6. The light-emitting diode according to claim 1, characterized in that a thickness of the electron blocking layer is 1% to 3000% of a thickness of the light-emitting layer.

7. The light-emitting diode according to claim 1, characterized in that a content of aluminum in the electron blocking layer ranges from 15% to 20%.

8. The light-emitting diode according to claim 1, characterized in that a thickness of the connecting layer is less than a thickness of the electron blocking layer.

9. The light-emitting diode according to claim 1, characterized in that a concentration of the indium doped in the connecting layer is uniformly distributed.

10. The light-emitting diode according to claim 1, characterized in that a concentration of the indium doped in the connecting layer gradually decreases in a direction from the P-type semiconductor layer toward the N-type semiconductor layer, and a thickness of the connecting layer ranges from 500 angstroms to 900 angstroms.

11. The light-emitting diode according to claim 10, characterized in that the concentration of the indium doped in the connecting layer on one side close to the P-type semiconductor layer is at least 1.5 times the concentration of the indium doped in the connecting layer on one side close to the N-type semiconductor layer.

12. The light-emitting diode according to claim 1, characterized in that the light-emitting diode further comprises an N-type electrode, a P-type electrode and an insulation layer, wherein the insulation layer covers the P-type semiconductor layer, the light-emitting layer and the N-type semiconductor layer, the insulation layer has a first opening and a second opening, the N-type electrode is connected to the N-type semiconductor layer through the first opening, the P-type electrode is connected to the P-type semiconductor layer through the second opening.

13. The light-emitting diode according to claim 1, characterized in that a proportion of the indium doped in the connecting layer ranges from 0.1% to 5%.

14. The light-emitting diode according to claim 1, characterized in that the light-emitting diode is a gallium nitride light-emitting diode.

15. A light-emitting device, characterized in that the light-emitting device comprises a circuit board and a light-emitting diode, wherein the light-emitting diode is disposed on the circuit board, and the light-emitting diode adopts the light-emitting diode according to claim 1.
